(19) United States
(12) Patent Application Publication
(10) Pub. No.: US 2026/0327784 A1
(43) Pub. Date: Oct. 22, 2026

(54) METHOD AND APPARATUS FOR PRODUCING A SUPPORT STRUCTURE, SUPPORT STRUCTURE AND OPTICAL DEVICE WITH A SUPPORT STRUCTURE

(71) Applicant: Max-Planck-Gesellschaft zur Foerderung der Wissenschaften e. V., Muenchen (DE)

(72) Inventor: Sebastian RABIEN, Landshut (DE)

(21) Appl. No.: 19/107,703

(22) PCT Filed: Sep. 1, 2023
(86) PCT No.: PCT/EP2023/074004

§ 371 Date: Feb. 28, 2025

(30) Foreign Application Priority Data
Sep. 2, 2022 (DE) 10 2022 122 315.9

(51) Int. Cl. C23C 14/50

(52) U.S. Cl. CPC C23C 14/505

(57) ABSTRACT

Disclosed is a method for producing a support structure for supporting at least one functional unit, preferably for an optical device, in a reaction chamber, including: providing a liquid medium for shaping support structure during production and/or in a production state, preferably in a receiving device configured to be semi-open at least in sections; moving the liquid medium and generating a shaping surface thereof, preferably by driving receiving device using a drive device or by driving an apparatus having a reaction chamber in which receiving device is arranged; providing a reaction material for forming support structure, preferably using at least one inlet device spaced apart from receiving device in the reaction chamber; applying the reaction material onto the shaping surface; constructing support structure using the applied reaction material. Further disclosed is an apparatus for producing support structure, a support structure and an optical device with at least one support structure.

### DESCRIPTION

The present invention is in the field of coating methods and relates to an apparatus and a method for producing a support structure, a support structure and an optical device with a support structure.

Coating methods in the form of physical and chemical coating methods are known in numerous variants and applications from the state of the art. For example, the term “physical vapor deposition” refers to a group of coating methods that take place in a vacuum environment. Here, a starting material is converted into the gaseous aggregate state, i.e. into the gas phase, by means of physical methods and then guided to a substrate or object to be coated. The gaseous starting material then condenses and a coating is formed onto the substrate or object, which consists of the starting material in a solid aggregate state. Such methods are used in microelectronics, for example, and are used to coat, for example, electronic components made from semiconductor materials.

The so-called “chemical vapor deposition” refers to a group of coating methods in which a solid is deposited from gaseous starting material and formed on a surface of a substrate or an object due to chemical reactions. In other words, at least one chemical reaction takes place on the surface of the substrate or object. Generally, a solid layer of the gaseous material is deposited at certain pressure and temperature conditions or in certain pressure and temperature ranges.

Coating methods are also known from the prior art patent literature.

US patent application No. US 2003/0223135 A1 describes a method for producing a parabolic membrane mirror. A liquid contained in a cylindrical container is rotated over the cylindrical container to generate a parabolic inverted mandrel. A fast-curing liquid polymer is then poured into the inverted mandrel to form a substrate for the membrane mirror. After the substrate is cured, a reflective coating is formed by applying a curing and reflective substrate.

US patent application No. US 2002/0126726 A1 describes a method for producing an optical membrane device (“MEMS membrane”) with an integral mirror and optically arched surface. The substrate is a silicon-based disc (“silicon wafer”), which is oxidized to form an insulating sacrificial/separating layer and also to define an electrostatic cavity. An arched optical layer is applied to the sacrificial/separating layer by deposition through a silicon wafer material, which is then selectively removed. The arched surface can also be formed by polishing or alternatively by etching.

A method for producing a selective membrane from parylene is known from the published European patent specification no. EP 1 672 394B1 . The method comprises providing a container with a liquid, for example oil. The liquid and the edge of the container are covered with a homogeneous, uninterrupted thin layer of parylene by means of a low-pressure deposition process. The layer of parylene forms the membrane and adheres to the container. Once the layer is formed, the liquid is drained from the container, leaving the thin layer in its original position, thus forming a film of parylene stretched between the walls of the container. The film is then micro-perforated by laser melting to form the selective membrane. The film can also be made porous by ion etching. The selective membrane serves as a filter for a gas or other fluid.

It is an object of the present invention to provide an improved method and an improved apparatus for producing a support structure for supporting at least one functional unit, preferably in the form of an optically active coating or at least one optically active layer. Furthermore, it is an object of the present invention to provide a support structure for supporting the at least one functional unit, the preferably mechanical-structural and/or geometric properties of which are improved. In addition, it is an object of the present invention to provide an optical device with such a support structure. It is further an object of the present invention to provide a mirror, in particular parabolic mirror or spherical mirror or membrane mirror, with a predetermined focal length, as well as a method for producing the same.

The object is solved by the features of claims 1, 10, 13, 14, 19 and 20. Further embodiments and applications of the present invention result from the dependent claims and are explained in more detail in the following description with partial reference to the figures. According to a first general aspect, the present invention relates to a method for producing a support structure for supporting at least one functional unit, preferably for an optical device, in a reaction chamber, comprising: providing a liquid medium for shaping the support structure during the production and/or in a production state, preferably in a receiving device which is configured to be semi-open at least in sections; setting the liquid medium in motion and/or moving the liquid medium and generating a shaping surface of the liquid medium, preferably by driving the receiving device by means of a drive device or by driving an apparatus which comprises a reaction chamber in which the receiving device is arranged; providing a reaction material for forming the support structure, preferably by means of or via at least one inlet device, wherein the at least one inlet device and the receiving device are arranged spaced apart from one another in the reaction chamber; applying, preferably depositing, the reaction material onto the shaping surface; constructing the support structure by means of the applied, preferably deposited, reaction material.

The method according to the present invention is preferably a coating method in which the material of the coating and thus the reaction material forms the support structure. Furthermore, the method according to the present invention is characterized in that a liquid medium set in motion and thus a liquid serves as the shape of the support structure to be produced. In particular, the moving surface of the liquid medium contributes to shaping the support structure in the course of its production by means of the reaction material.

Depositing preferably involves a direct and/or immediate transition or transfer of the reaction material from a gaseous aggregate state to a solid aggregate state. A liquid state of aggregation is thus omitted.

The present method can be used, for example, to form a substantially rotationally symmetrical support structure from a reaction material, which is also substantially homogeneous, for example over its entire extension. The support structure can preferably be a curved or arched support structure. The support structure can be sufficiently dimensionally stable to support the at least one functional unit. The at least one functional unit can preferably be a coating or at least one layer and can provide a certain functionality. For example, the at least one functional unit can be a layer of a light-reflecting metallic material, for example aluminum or gold.

The method according to the present invention can be characterized by further features, which will be described in more detail below.

The reaction material can be configured as a gaseous and/or separable reaction material at least before the constructing of the support structure. In addition or alternatively, or at least after the constructing of the support structure, the reaction material can be configured as a solid reaction material. The produced support structure can thus preferably be characterized by defined geometric dimensions after the production and comprise, for example, a substantially constant thickness. The reaction material in the sense of the present invention is preferably a reactive material which constructs the support structure only by application, preferably deposition, onto the shaping surface, preferably continuously or preferably constantly. In other words, the reaction material is a self-reacting, preferably chemically reacting, material during application and/or during construction, which constructs the support structure by generating chemical bonds. The reaction material is preferably a sublimable and/or resublimable material.

According to a further aspect of the present invention, the method can comprise: evaporating, preferably by means of heating to a certain temperature or a certain temperature range, the reaction material and/or transforming the reaction material from a solid aggregate state to a gaseous aggregate state, preferably in an evaporation device, and/or pyrolyzing and thus cutting the reaction material, preferably in a pyrolysis device and at certain pressure and temperature conditions or in certain pressure and temperature ranges. The reaction material can be such that it sublimates at certain temperature conditions and/or pressure conditions, i.e. it changes or transitions directly from a solid aggregate state to a gaseous aggregate state and vice versa. The reaction material can be brought into a reactive state primarily by pyrolysis in order to produce the support structure by constructing accordingly.

Constructing the support structure can comprise: accumulating, preferably adsorbing, the reaction material on the shaping surface, and/or generating chemical bonds in the reaction material, and/or constructing the support structure in the form of at least one layer and/or at least one membrane, which preferably comprises a substantially constant thickness and/or is configured substantially homogeneously.

Constructing the support structure thus preferably comprises solidifying the reaction material by generating chemical bonds in order to achieve a defined or sufficient dimensional stability.

Setting the liquid medium in motion and/or moving the liquid medium can comprise rotating the liquid medium or setting the liquid medium in rotation at an adjustable speed, preferably by means of the drive device and/or dependent on at least one operating condition and/or geometric variable of the support structure; and/or forming the shaping surface, which is configured to be curved or arched, preferably paraboloidal and/or concave, at least in sections, and thus in the form of a paraboloid. Preferably, the speed (rotational/angular speed of the receiving device and of the liquid medium in the state in which the liquid medium has assumed the rotational speed of the receiving device) is set as a function of a focal length of the mirror to be produced. In other words, the following can be provided: setting of a speed, preferably rotational speed, of the receiving device and/or of the liquid medium as a function of a focal length of a mirror to be produced, wherein preferably the liquid medium has substantially assumed the speed, preferably rotational speed, of the receiving device. Due to the rotational movement, the at least partially curved or arched surface is advantageously formed.

According to a further aspect of the present invention, the method can comprise: generating a negative pressure and/or preferably a vacuum in the reaction chamber at least before the providing of the reaction material, preferably by means of or via at least one outlet device and a pumping device, wherein the pumping device is arranged outside the reaction chamber, and/or wherein the at least one outlet device and the receiving device are arranged spaced apart from one another in the reaction chamber.

By generating negative pressure and preferably a vacuum, a reaction chamber can be provided which is substantially free of foreign substances, for example. Furthermore, this can ensure a substantially uniform distribution of the reaction material in the reaction chamber.

By generating, preferably continuously generating, and/or providing a vacuum, preferably a high vacuum, in the reaction chamber, an improved constructing of the support structure by means of the reaction material is thus realized, for example, preferably by means of depositing from the gaseous aggregate state.

It is possible that the method comprises: directed distributing of the reaction material at at least one defined point in the reaction chamber, preferably in each case in the direction of the shaping surface, preferably by means of at least one distribution device, the at least one distribution device being connected to the at least one inlet device. The distribution device can, for example, comprise at least one nozzle device and/or at least one guide device in order to guide the reaction material in a defined direction at least in the region of or at the distribution device.

According to a further aspect of the present invention, the method can comprise: detecting a geometric variable, preferably a thickness, of the support structure during the application of the reaction material and/or constructing of the support structure, preferably by means of at least one measuring device for detecting the geometric variable, wherein the at least one measuring device is arranged in the reaction chamber, and/or wherein the at least one measuring device and the receiving device are arranged spaced apart from one another in the reaction chamber.

This can, for example, ensure more or less continuous monitoring of the construction of the support structure. Depending on the detected thickness of the support structure, the volume flow of the reaction material into the reaction chamber can be regulated or controlled, for example.

It is possible that the method comprises: setting at least one operating condition of the method, preferably by means of a control device, wherein the at least one operating condition comprises at least one of the following: a temperature in the reaction chamber, a temperature of the reaction material before being provided in the reaction chamber, a pressure in the reaction chamber, a temperature of the liquid medium; a time period of the providing of the reaction material, a volume flow of the reaction material, and/or a drive speed of the receiving device, and/or a volume flow of the reaction material.

According to a second general aspect, the present invention relates to a support structure for supporting at least one functional unit, preferably for an optical device, wherein the support structure is produced according to a method as disclosed herein, wherein the support structure is at least in the production state dimensionally stable at least in sections, and/or wherein the support structure is reversibly foldable and/or reversibly rollable.

In other words, the support structure can be folded and/or rolled up due to its geometric and/or mechanical-structural properties and can resume its original geometric configuration after being unfolded or rolled out.

As already described, the support structure can be configured to be curved or arched, preferably paraboloidal and thus in the form of a paraboloid, at least in sections, and/or the support structure can be configured from a reaction material which comprises a parylene and/or at least one derivative based on a parylene. In other words, the reaction material can comprise at least one material from the group of poly-p-xylylenes and/or derivatives thereof.

Preferably, the at least one functional unit is configured on a concave surface of a curved or arched support structure in such a way that the support structure and the at least one functional unit formed thereon form a mirror, in particular a parabolic mirror, spherical mirror or membrane mirror, with a predetermined focal length.

The support structure can support at least one functional unit, wherein the at least one functional unit comprises at least one coating or at least one layer, which is formed substantially from a metallic material and/or from a light-reflecting material.

According to a third general aspect, the present invention relates to an optical device, preferably an optical telescope or an optical membrane mirror, comprising at least one support structure for supporting at least one functional unit, wherein the support structure is produced and/or configured as disclosed herein and wherein the at least one functional unit is produced and/or configured as disclosed and/or configured herein. The optical device can be used, for example, in a vacuum environment and/or in a cryogenic environment, for example in space.

According to a fourth general aspect, the present invention relates to an apparatus for producing a support structure for supporting at least one functional unit, preferably for an optical device, wherein the apparatus is preferably configured to carry out a method as disclosed herein, comprising: a reaction chamber which is formed by a reaction container and in which the support structure is producible; a receiving device for receiving a liquid medium serving to shape or for shaping the support structure during production and/or in a production state, wherein the receiving device is arranged in the reaction chamber and/or is configured to be semi-open at least in sections; at least one inlet device for providing a reaction material into the reaction chamber and forming the support structure, wherein preferably the at least one inlet device and the receiving device are arranged spaced apart from one another in the reaction chamber; wherein the receiving device comprises or is coupled to a drive device for setting a received liquid medium in motion and/or moving it and thus generating a shaping surface of the liquid medium, wherein the reaction chamber and/or at least the at least one inlet device is configured for applying the reaction material onto the shaping surface in order to construct the support structure through it.

The drive device can be configured to drive the receiving device rotationally at an adjustable speed, i.e. rotating, preferably dependent on at least one operating condition when the apparatus is in operation. The receiving device can be configured to be semi-open, preferably semi-open cylindrical, plate-shaped or shell-shaped. It is possible that the receiving device is configured to be curved or arched, at least in sections. The receiving device can comprise a circumferential edge or a circumferential rim, which serves to limit the amount and thus the volume of liquid medium received. Preferably, a defined amount of liquid medium can be received in the receiving device so that the surface of the liquid medium transitions substantially flush and/or substantially continuously onto the circumferential edge or onto the circumferential rim during the movement of the receiving device and thus during the movement of the liquid medium. This prevents, for example, the forming of undesirable curvatures on the support structure.

According to a further aspect of the present invention, it can be provided that the apparatus comprises at least one bearing device for bearing the receiving device, wherein the at least one bearing device is configured for substantially vibration-free or sufficiently vibration-free bearing of the receiving device, preferably comprising at least one magnetic bearing or at least one hydrostatic bearing. This can, for example, further improve the quality of the produced support structure, since no or at least hardly any harmful disturbances can occur as a result of time-dependent mechanical loads during the production.

It is possible that the apparatus comprises at least one barrier device for protecting the at least one bearing device in order to prevent the reaction material from entering the at least one bearing device, wherein the at least one barrier device encloses the at least one bearing device and/or comprises at least one labyrinth seal and/or at least one liquid seal. According to a further aspect of the present invention, it can be provided that the apparatus comprises a coating device for coating the support structure with a coatable material, that is a coating material, preferably based on a metallic material, in order to form the at least one functional unit on the support structure.

According to a fifth general aspect, the present invention relates to a method for producing a mirror, in particular a parabolic or spherical mirror, comprising at least one support structure for supporting at least one functional unit, comprising: producing the support structure as disclosed herein, and applying or coating at least one functional unit on a concave side of a curved or arched surface of the at least one support structure, wherein the at least one functional unit comprises at least one coating or at least one layer, which is formed from a metallic material and/or from a light-reflecting material.

According to a sixth general aspect, the present invention relates to a mirror, preferably a parabolic or spherical mirror, which is preferably produced according to the method as disclosed herein, comprising: at least one support structure, wherein the at least one support structure is produced and/or configured as disclosed herein, and at least one functional unit being formed on a concave side of a curved or arched surface of the support structure, wherein the at least one functional unit preferably comprises a coating or at least one layer, which is formed from a metallic material and/or from a light-reflecting material. To avoid repetition, features directed purely to the apparatus according to the invention and/or disclosed in connection therewith shall also be deemed to be disclosed and claimable according to the method and vice versa.

The embodiments and features of the present invention described above can be combined with one another in any manner. Further or other details and advantageous effects of the present invention are explained in more detail below with reference to the accompanying figures.

It shows:

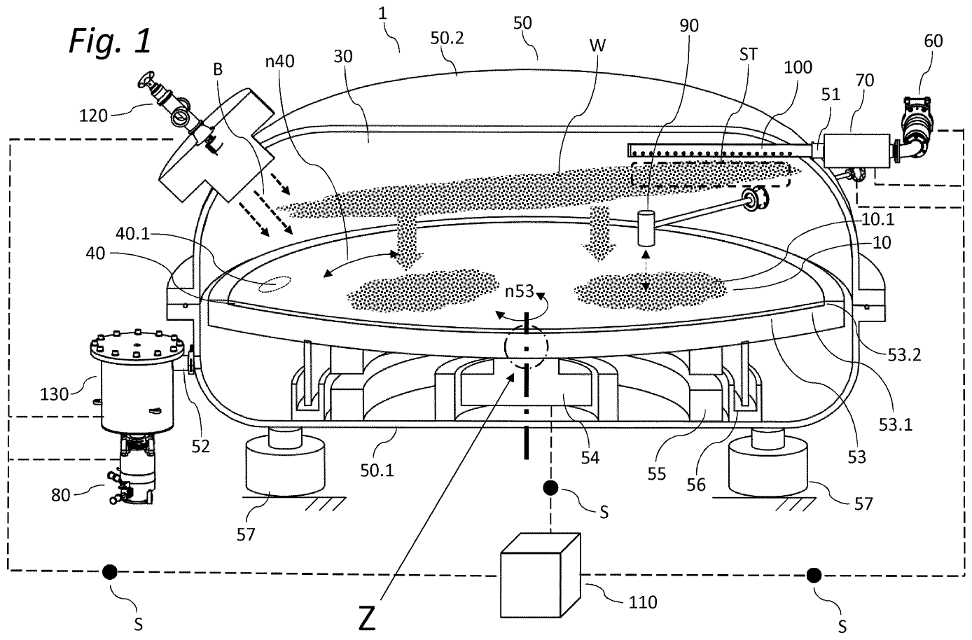

FIG. 1 a first embodiment of the apparatus for producing the support structure according to the present invention in a schematic illustration and in a sectional view;

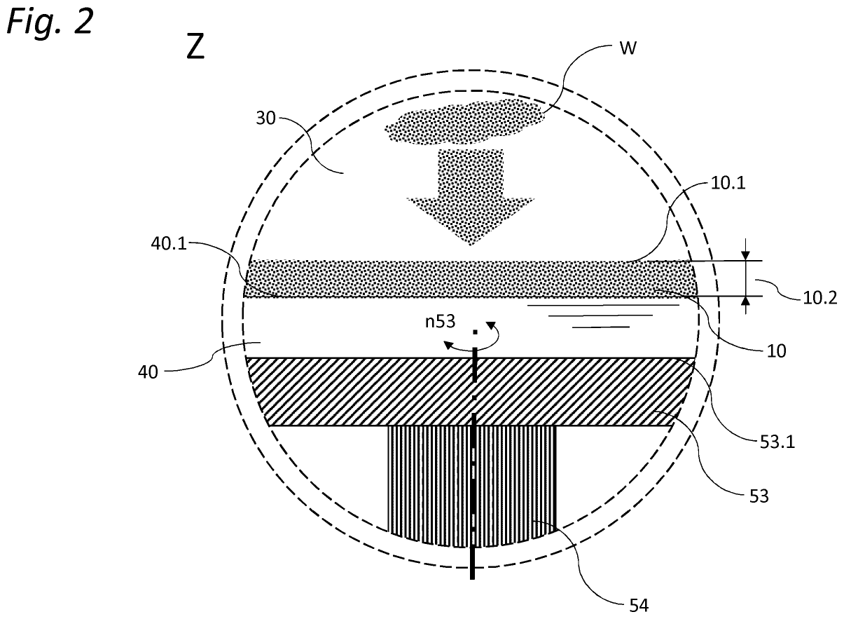

FIG. 2 a section of the support structure from FIG. 1 (section Z in FIG. 1) in an enlarged illustration;

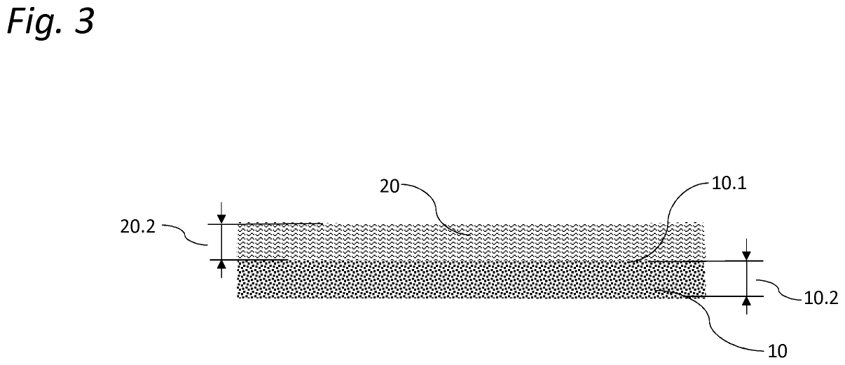

FIG. 3 an example of a support structure according to the present invention in a schematic illustration;

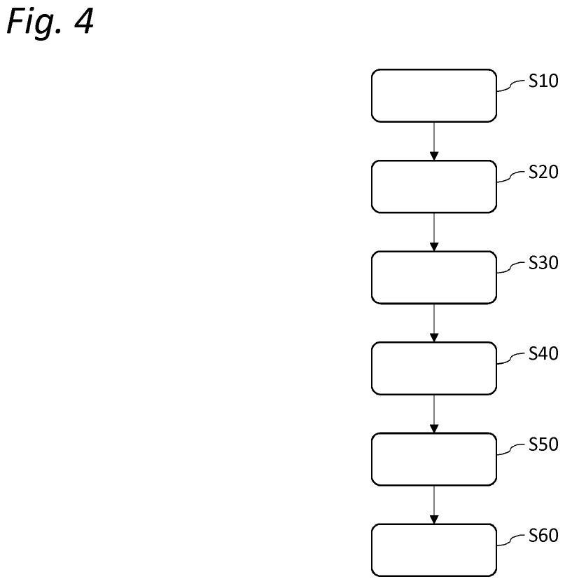

FIG. 4 a flow chart for an example of the method for producing the support structure according to the present invention.

Identical or functionally equivalent components or elements are marked with the same reference signs in the figures. For their explanation, reference is also made in part to the description of other embodiments and/or figures in order to avoid repetitions.

The following detailed description of the embodiments shown in the figures serves to illustrate or clarify in more detail and is in no way intended to limit the scope of the present invention.

FIG. 1 shows a first embodiment of the apparatus 1 for producing the support structure 10 according to the invention or a mirror according to the invention with a predetermined focal length in a schematic illustration. The apparatus 1 is shown in a sectional view for illustration purposes.

The apparatus 1 comprises a reaction chamber 30. In the reaction chamber 30, under respective operating conditions, the support structure 10 can be produced from a reaction material W according to the method of the present invention as disclosed herein. The support structure 10 serves for supporting a functional unit 20, the functional unit 20 preferably comprising a coating or at least a layer of a light-reflecting material.

In the following, the reaction material W and the apparatus 1 are first described with reference to FIGS. 1 and 2.

The reaction material W for forming the support structure 10 is preferably a separable reaction material W. Preferably, the reaction material W is a material or a mixture of several different materials, by means of which the support structure 10 can be formed using and/or according to the principle of so-called chemical vapor deposition (CVD). Preferably, the reaction material W comprises good dielectric properties and/or a low coefficient of thermal expansion and/or a low vapor pressure. Preferably, the reaction material W comprises at least one material from the group of poly-p-xylylenes and/or their derivatives (also referred to as “parylenes”).

To form the reaction chamber 30, the apparatus 1 comprises a reaction container 50. The reaction container 50 delimits the reaction chamber 30 from an environment and/or from an atmosphere, so that corresponding operating conditions can be changed in the reaction chamber 30 before and/or during the production of the support structure 10, preferably set in a defined manner by means of a regulation. In other words, the reaction container 50 isolates the reaction chamber 30 from the environment. This creates a reaction chamber 30 for producing the support structure 10, which can be set in a targeted, i.e. defined, manner with regard to the operating conditions.

The reaction container 50 comprises at least a first container housing part 50.1 and a second container housing part 50.2 with a corresponding wall. Both the first container housing part 50.1 and the second container housing part 50.2 are configured substantially rotationally symmetrical and/or hollow-cylindrical at least in sections. A maximum and/or resulting inner diameter of the first container housing part 50.1 and/or the second container housing part 50.2 can, for example, be approximately 40 centimeters or more. It is possible that the container housing 50 is configured in multiple parts and/or non-rotationally symmetrical. The first container housing part 50.1 and/or the second container housing part 50.2 can each be formed from a metallic material and/or with insulation.

The two container housing parts 50.1 and 50.2 are each preferably connected to one another via a flange with a corresponding circumferential seal (not marked in FIG. 1 for reasons of clarity) and sufficiently seal off the reaction chamber 30. In other words, the second container housing part 50.2 can be dismantled from the first container housing part 50.1. The two container housing parts 50.1 and 50.2 together form a reaction vessel.

In order to avoid mechanical loads, for example in the form of vibrations/oscillations or shocks, which could be introduced into the structure of the reaction container 50 and thus into the reaction chamber 30 and would disrupt the production process of the support structure 10, the apparatus 1 can comprise at least one damping device 57. The at least one damping device 57 is preferably arranged on an outer side (outside) of the bottom wall of the first container housing part 50.1 with respect to the reaction chamber 30 and can support the reaction container 50, for example with respect to a foundation or with respect to a mounting structure, and at the same time reduce or preferably avoid the introduction or transmission of mechanical loads as described above. This ensures, for example, a production process of the support structure 10 that is free from external mechanical loads. A receiving device 53 for receiving a liquid medium 40 is arranged within the reaction chamber 30. According to the invention, the liquid medium 40 and preferably the surface 40.1 of the liquid medium 40 is used in a certain state for shaping the support structure 10 during the production and/or in a production state of the support structure 10, which will be described in more detail below.

The receiving device 53 is configured to be semi-open and thus ensures an accessibility of the liquid medium 40, in particular the surface 40.1. The receiving device 53 is preferably configured to be substantially plate-shaped or substantially shell-shaped and/or preferably substantially rotationally symmetrical with respect to an axis of rotation (see the dotted line in FIG. 1). In relation to the present embodiment of the apparatus 1 according to the present invention, the receiving device 53 is preferably configured as a turntable with an external and/or circumferential edge 53.2. The edge 53.2 delimits a surface 53.1 of the receiving device 53, which comes into contact with and/or receives the liquid medium 40. Apart from a substantially circular section in the region of the edge 53.2, the surface 53.1 of the receiving device 53 is configured to be substantially curved and/or substantially arched. For example, the surface 53.1 can be configured substantially in the form of a paraboloid, at least in sections. The receiving device 53, and preferably the circumferential edge 53.2, can comprise, for example, an inner diameter of approximately 30 centimeters or more. In this way, a support structure 10 of, for example, at least approximately 30 centimeters in diameter or more can be produced. Preferably, the surface 53.1 of the receiving device 53 is substantially smooth. In an alternative embodiment of the present invention, it is possible for the receiving device 53 to have ribs and/or beads arranged on the surface 53.1 extending radially inwards at least in sections, which serve to set the liquid medium 40 in rotary motion as a result of a rotary motion of the receiving device 53 and thus to move the liquid medium 40.

Preferably, the receiving device 53 comprises on its outer sides, that is on its outer surfaces, preferably at least away from the surface 53.1 of the received liquid medium 40, a coating which is non-adhesive with respect to the reaction material W. For example, the receiving device 53 is coated with a kerosene or, particularly preferably, with polytetrafluoroethylene (abbreviated “PTFE”). In this context, it is possible that the inner sides of the container housing parts 50.1 and 50.2 and thus the respective inner surfaces of the container housing parts 50.1 and 50.2, as well as the components and elements of the apparatus 1 inside the reaction container 50 are also coated with a kerosene or preferably with polytetrafluoroethylene (abbreviated “PTFE”). This ensures, for example, that the reaction material W, which has been deposited or distributed away from the liquid medium 40, i.e. away from the surface 40.1 of the liquid medium 40 in the reaction chamber 30, can be removed more easily.

The receiving device 53 is rotatably and drivably mounted on an inner side of the bottom wall of the first container housing part 50.1 and thus within the reaction container 50 and can be set in motion in the course of producing the support structure 10 using a regulation and/or control system dependent on at least one operating condition. For this purpose, the receiving device 53 can be connected by means of a drive device 54 or mounted on the drive device 54.

The drive device 54 can, for example, be configured as an electric motor or comprise an electric motor. Alternatively, the drive device 54 an, for example, be configured as a magnetic drive unit or comprise a magnetic drive unit which is driven by a moving magnetic field, preferably a rotating magnetic field, inside the reaction container 50 or outside the reaction container 50.

The drive device 54 is preferably configured to provide a substantially constant rotational movement and thus a substantially constant rotational speed per time interval in the course of regulation and/or control over a defined set period of time, in order to ensure a substantially constant rotational movement of the receiving device 53 with this in turn. In other words, a substantially constant rotational speed n53 of the receiving device 53 is realized by means of the drive device 54. As already described above, the receiving device 53 serves on the one hand to receive the liquid medium 40. Here, the receiving device 53 comprises the surface 53.1, which contacts the liquid medium 40. Due to the rotational movement of the receiving device 53, the liquid medium 40 received therein is in turn set in motion. In other words, when the receiving device 53 is driven, a rotating and thus moving liquid medium 40 is set, the resulting and/or idealized speed of which is marked in simplified form with “n40” in FIG. 1.

A resulting axis of rotation of the receiving device 53 can be aligned and/or arranged substantially parallel to the force of gravity, i.e. gravitational force. This is preferably ensured by a bearing device 55 of the receiving device 53, which will be described in more detail in the following. Due to the rotational movement of the receiving device 53, the liquid medium 40 is at least partially “pressed” in the direction of the edge 53.2 of the receiving device 53 due to its mass and thus the centrifugal forces acting on it, and a shaping, curved or arched surface 40.1 of the liquid medium 40 in motion is formed, preferably substantially in the form of a paraboloid. The shape of the paraboloid depends in particular on the rotational speed n53. In particular, the rotational speed n53 (rotational/angular speed) is set as a function of the focal length of a mirror to be produced with the apparatus 1. In other words, the rotation of the mass of the liquid medium 40 in the receiving device 53 under the influence of gravity and centrifugal force due to the rotational movement results in a substantially parabolic surface 40.1 of the liquid medium 40 as the shaping surface 40.1 for the support structure 10 to be produced.

In an alternative embodiment of the present invention, it can be provided to set the apparatus 1 and preferably the reaction container 50 together with the components and elements arranged within the reaction container 50 as a whole into a rotational movement instead of the receiving device 53. A resulting axis of rotation can be aligned and/or arranged substantially parallel to gravity, i.e. gravitational force.

The liquid medium 40 is preferably a liquid medium 40 with a comparatively high density and/or high viscosity. This also makes it possible, for example, to reduce or substantially avoid mechanical stresses or disturbances, preferably on the surface 40.1 for shaping the support structure 10; on the other hand, this simplifies or facilitates the formation of the support structure 10 by the reaction material W on the surface 40.1, which will be described in more detail in the following.

For example, the liquid medium 40 can be an ionic liquid, a liquid polymer, a paraffinic hydrocarbon or, for example, a polyphenyl ether in a liquid aggregate state. The liquid medium 40 can preferably comprise a low vapor pressure at room temperature, wherein the room temperature for the purposes of the present invention is approximately 293.15 Kelvin, that is approximately 20 degrees Celsius.

Within the reaction container 50, the receiving device 53 may preferably comprise a bearing device 55 which, in addition to or as an alternative to the at least one damping device 57 of the apparatus 1, reduces or preferably avoids mechanical loads. The bearing device 55 can, for example, be configured as at least one hydrostatic bearing or as at least one magnetic bearing, or comprise at least one hydrostatic bearing or at least one magnetic bearing. The working fluid of the hydrostatic bearing can preferably be an oil or based on an oil. In other words, the apparatus 1 comprises a bearing device 55 for bearing the receiving device 53, wherein the bearing device 55 is configured for substantially vibration-free bearing of the receiving device 53.

In order to protect the bearing device 55 in particular from entering the reaction material W and thus to avoid wear and/or damage to the bearing device 55, the apparatus 1 comprises a barrier device 56 for protecting the bearing device 55. The barrier device 56 preferably encloses the bearing device 55 in such a way that contact with the reaction material W is avoided or is not possible. In other words, the barrier device 56 can be configured to seal off the bearing device 55 from the reaction chamber 30. For this purpose, the barrier device 56 may comprise at least one labyrinth seal and/or at least one liquid seal. As a liquid barrier, the liquid seal can, for example, at least partially absorb the reaction material W, which has not contributed to the formation of the support structure 10 and has distributed itself accordingly in the reaction chamber 30. The liquid of the liquid barrier can then, for example, be pumped out and removed from the interior of the reaction container 50, that is, from the reaction chamber 30, in a simple manner. It is understood that the barrier device 56 is configured to also protect the drive device 54 from the reaction material W.

To feed the reaction material W into the reaction chamber 30, the reaction container 50 of the apparatus 1 and in this case the second container housing part 50.2 comprises at least one inlet device 51. The inlet device 51 is preferably arranged spaced apart from the receiving device 53, i.e. arranged at a certain distance, in order to ensure a substantially homogeneous distribution of the reaction material W in the course of the production of the support structure 10. In order to achieve an improved distribution of the reaction material W in the reaction chamber 30 and towards the surface 40.1 of the liquid medium 40, a distribution device 100 can be located in the reaction chamber 30 at the inlet device 51 and thus inside the reaction container 50 and can be connected to the inlet device 51, i.e. connected by fluid mechanics. The distribution device 100 can, for example, be configured in the form of a tube and extend substantially in a straight line up to a certain length. The distribution device 100 can additionally or alternatively be configured to be arched, at least in sections. The distribution device 100 comprises at least one inlet opening, preferably a plurality of inlet openings, through which the reaction material W can flow into the reaction chamber 30 at a certain point ST in the course of the production of the support structure 10. The plurality of inlet openings are shown in simplified form as black dots in the distribution device 100 in FIG. 1 and are not marked in more detail. It is possible that the distribution device 100 comprises valve devices and/or propeller devices instead of the inlet openings, at least in part or in total, which contribute to changing the kinetic energy of the reaction material W before and/or after it enters the reaction chamber 30 and/or to a targeted distribution of the reaction material W in the reaction chamber 30.

Outside the reaction container 50, the inlet device 51 is fluid-mechanically connected to an evaporation device 60 and preferably to a pyrolysis device 70. The pyrolysis device 70 is arranged fluid mechanically between the evaporation device 60 and the inlet device 51. The evaporation device 60 serves to heat and evaporate and, in particular, to sublimate the reaction material W, i.e. to convert the reaction material W directly from a solid aggregate state into a gaseous aggregate state.

The reaction material W is based on or preferably comprises, as already described above, a material from the parylene group and can, for example, be processed using the so-called Gorham process in order to form the support structure 10.

At the beginning of the production of the support structure 10, the reaction material W is preferably present in the evaporation device 60 as a solid, granular raw material. This raw material is also referred to as a “dimer” and chemically concerns largely stable “dimer molecules” of the reaction material W.

In the evaporation device 60, the reaction material W is preferably converted from the solid aggregate state to the gaseous aggregate state. In other words, the evaporation device 60 is configured to treat the reaction material W with heat so that the reaction material W sublimates. This can take place, for example, in a temperature range between about 120 degrees Celsius and about 180 degrees Celsius, at about one bar ambient pressure. For this purpose, the evaporation device 60 comprises a correspondingly configured heating unit, which is not shown and not marked in FIG. 1 for reasons of clarity. The reaction material W thus evaporates into a dimeric gas.

The pyrolysis device 70 is configured to pyrolyze the reaction material W and preferably the vaporized and/or gaseous reaction material W, i.e. to split it thermochemically and convert it into a highly reactive monomeric form. In other words, the pyrolysis device 70 comprises a high-temperature zone for generating so-called reactive monomers of the reaction material W from the gaseous reaction material W. For example, the temperature in the pyrolysis device 70 can be approximately 690 degrees Celsius.

The reaction material W then enters the reaction chamber 30 of the reaction container 50 in an activated gaseous state via the inlet device 51.

In a further or alternative embodiment of the apparatus 1, it is possible that at least one regulable and/or controllable valve device is arranged between the evaporation device 60 and the pyrolysis device 70, which is fluid-mechanically connected to the evaporation device 60 and to the pyrolysis device 70. The at least one valve device can be configured, in particular, to set the volume flow of the reaction material W in a defined manner dependent on at least one operating condition and/or in the course of the regulation and/or control of the apparatus 1. For example, the valve device can be used to regulate and/or control a so-called growth rate of the support structure 10 by enriching the reaction material W and preferably to start production of the support structure 10 at a defined rate, i.e. at a defined volume flow of reaction material W.

In an alternative embodiment of the apparatus 1 according to the present invention, it is possible that, in addition to an inlet device 51, a second inlet device 51 or more than two further inlet devices 51 are formed on the reaction container 50 and here preferably on the second container housing part 50.2.

In addition to at least one inlet device 51, the apparatus 1 according to the present invention comprises at least one outlet device 52. The outlet device 52 is formed on the reaction container 50 and here preferably on the first container housing part 50.1. In other words, the at least one outlet device 52 is arranged on the reaction container 50 on a side opposite the at least one inlet device 51 with respect to the receiving device 53. Via the outlet device 52, a negative pressure and preferably a vacuum is generated in the reaction container 50 and thus in the reaction chamber 30 in the course of the production of the support structure 10. The outlet device 52 is connected to a pumping device 80 in the form of a vacuum pump. The pumping device 80 is configured to generate a negative pressure and preferably a vacuum in the reaction container 50, that is, in the reaction chamber 30. In other words, the pumping device 80 is configured to sufficiently evacuate the reaction chamber 30 at least before and preferably during the production of the support structure 10, so that at least proper and/or intended functionality and safety of the apparatus 1 for producing the support structure 10 is ensured. Thus, for example, the reaction chamber 30 is largely or substantially freed from foreign substances that could interfere with the production, i.e. the production process, and thus negatively influence the quality of the support structure 10. In addition, the continuous formation of a vacuum in the reaction container 50 ensures a substantially uniform and/or homogeneous distribution of the reaction material W over the shaping surface 40.1 of the moving liquid medium 40. For example, pressures of less than 100 Pascal, preferably less than 10 Pascal and particularly preferably less than 0.1 Pascal can be realized in the reaction chamber 30 by means of the pumping device 80. For further processing and/or treatment of the produced support structure 10 in the form of coating the support structure 10 with a coating material B to form the functional unit 20, the pumping device 80 can be configured to generate a pressure in the reaction chamber 30 which is preferably in a portion between about 0.0001 Pascal and about 0.001 Pascal.

A cooling device 130 is preferably arranged between the outlet device 52 and the pumping device 80, which is fluid-mechanically connected to the outlet device 52 and to the pumping device 80. The cooling device 130 is configured to cool reaction material W exiting via the at least one outlet device 52, for example at less than −50 degrees Celsius, and to convert it into a solid aggregate state, so that the reaction material W is prevented from flowing further to the pumping device 80, from entering the pumping device 80 and from wearing out and/or damaging it. In other words, the cooling device 130 serves to protect the pumping device 80 from the reaction material W.

The apparatus 1 further comprises a coating device 120. The coating device 120 is preferably arranged on the second container housing part 50.2 and/or configured for introducing a coating material B into the reaction chamber 30 after the support structure 10 has been produced, in order to apply the coating material B to the support structure 10, that is, to coat the support structure 10 with the coating material B and thus to form the at least one functional unit 20 on the support structure 10. The functional unit 20 preferably comprises a coating or at least one layer of a substantially metallic material and/or of a light-reflecting material. Preferably, the coating material B for forming the functional unit 20 comprises aluminum or an alloy based on aluminum. It is also possible that the coating material B preferably comprises gold or an alloy based on gold. To ensure that the coating device 120 is not contaminated by the reaction material W during the production of the support structure 10 and/or clogged by deposits of reaction material W, the coating device 120 comprises a so-called shutter solution in the form of a closable aperture or a closable lid, which opens and/or closes the coating device 120 with respect to the reaction chamber 30. The aluminum can be applied to the support structure 10 as coating material B in the reaction chamber 30 and under appropriately set operating conditions by evaporation and/or atomization.

The apparatus 1 according to the present invention comprises, for realizing the production of the support structure 10 and thus for carrying out the method according to the present invention, a control device 110 for controlling and/or regulating at least respective components and elements of the apparatus 1 as disclosed herein. In other words, the control device 110 is used for the defined setting of, in particular, the drive device 54, the evaporation device 60, the pyrolysis device 70, the pumping device 80, and/or the cooling device 130 in the course of the production of the support structure 10. The control device 110 is preferably connected to the components and elements of the apparatus 1 for control and/or regulation via a signal communication network, which is used for transmitting corresponding signals S and thus information (see the dashed lines in FIG. 1). In other words, the components and elements of the apparatus 1 can be controlled and/or regulated at least before and/or during the production of the support structure 10. The regulation is characterized in particular by a closed loop and preferably ensures that certain operating conditions, such as respective temperatures, rotational speeds and/or pressures, remain substantially defined, preferably substantially constant, over a defined period of time in order to realize the production process of the support structure 10 as intended and/or properly.

So that a support structure 10 with defined and thus desired dimensions, for example with a defined thickness 10.2 (see for example FIG. 2), can be produced by means of the apparatus 1, the apparatus 1 preferably comprises several measuring devices with respective sensors or sensor units for detecting respective operating conditions of the components and elements of the apparatus 1 inside the reaction container 50 and outside the reaction container 50, as well as for detecting dimensions of the support structure 10, preferably at least before and during its production. For example, in FIG. 1, the measuring device 90 for detecting geometric dimensions and/or homogeneity of the forming support structure 10, for example the thickness 10.2 of the support structure 10, is arranged in the reaction chamber 30 and preferably on the second container housing part 50.2. The measuring device 90 is shown in FIG. 1 as representative of further measuring devices of the apparatus 1 according to the invention, which are used for detecting at least one operating condition and/or at least one geometric dimension (growth rate) or physical property of the support structure 10, preferably at least before and during the production of the support structure 10.

In a further embodiment of the apparatus 1, it is possible, for example, that the receiving device 53 is connected to and/or arranged on an adjusting device for adjusting the location and thus the position and/or the orientation of the receiving device 53 (not shown in the figures) inside the reaction chamber 30. For this purpose, the adjusting device can comprise, for example, at least one operable actuator unit in the form of a double-acting cylinder which, by corresponding actuation by means of a working medium, is capable of setting and thus changing the position of the receiving device 53 inside the reaction chamber 30. Thus, for example, a distance between the receiving device 53 and the inlet device 53 and/or the distribution device 100 can be changed.

It is also possible, for example, that the receiving device 53 comprises an integrated cooling device, for example in the form of a spirally arranged line system, through which a cooling medium preferably flows at least during the production of the support structure 10 in order to set a certain temperature for the liquid medium 40 and to ensure that the support structure 10 is constructed.

It is possible that, in a further embodiment of the apparatus 1 according to the present invention, the apparatus 1 comprises a plasma device for generating an ionized gas in order to process the support structure 10. This allows, for example, in particular the quality of the support structure 10, i.e. the quality of at least one layer of the support structure 10 and/or the surface 10.1 of the support structure 10, to be improved. The plasma device is preferably arranged in the reaction chamber 30, i.e. inside the reaction container 50 of the apparatus 1. The ionized gas can comprise argon, for example, as the working medium.

The support structure 10 is formed by the solidifying reaction material W, which preferably transitions from a gaseous aggregate state to a solid aggregate state by means of deposition and forms chemical bonds, which will be described in more detail in the following. The support structure 10 is preferably a support structure which is substantially rotationally symmetrical and/or sufficiently dimensionally stable with respect to an axis of rotation in order to support and/or carry the functional unit 20.

Preferably, a certain volume, i.e. a defined amount of liquid medium 40, is received in the receiving device 53, so that a substantially flush and/or continuous transition to the circumferential edge 53.2 of the receiving device 53 is provided, preferably during the rotational movement of the receiving device 53 and thus during the movement of the liquid medium 40.

FIG. 2 shows a section of the support structure 10 from FIG. 1 (section Z in FIG. 1) in an enlarged view.

The liquid medium 40 wets the surface 53.1 of the receiving device 53 as a contact surface. The reaction material W is in turn deposited on the surface 40.1 of the liquid medium 40 as a shaping surface for the reaction material W during the movement of the liquid medium 40, whereby the support structure 10 is formed from the deposited reaction material W with a corresponding thickness 10.2.

FIG. 3 shows a schematic illustration of an example of a support structure 10 according to the present invention, which supports a functional unit 20 in the form of a coating or at least a layer of a particular material. The functional unit 20 is preferably formed from a substantially metallic material and/or from a light-reflecting material by means of at least one coating process on the surface 10.1 of the support structure 10. The metallic and/or light-reflecting material can, for example, be aluminum or an alloy based on aluminum, as already described above.

The support structure 10 is formed substantially homogeneously over its dimensions from the solidified reaction material W. Furthermore, the support structure 10 comprises a substantially circular outer contour due to the production process. Overall, the support structure 10 comprises a substantially membranous configuration and is characterized by a curved shape. Furthermore, the support structure 10 can be configured to be substantially rotationally symmetrical with respect to an axis of rotation and comprise a substantially constant thickness 10.2 in the radial direction and in the circumferential direction. The thickness 10.2 of the support structure 10 together with a thickness 20.2 of the functional unit 20, which is supported by the support structure 10, can be, for example, 140 micrometers. The thickness 10.2 of the produced support structure 10 together with a thickness 20.2 of the functional unit 20 is, for example, in a portion between about 100 micrometers and about 1000 micrometers.

FIG. 4 shows a flow chart for an embodiment of the method for producing the support structure 10 according to the present invention.

Method steps are described below. The method for producing the support structure 10 can be carried out with the apparatus 1 as disclosed herein. The description of components and elements of the apparatus 1 according to the invention is therefore omitted at least in part in order to avoid repetition. In the following, particular emphasis will be placed on method steps of the method according to the invention.

In step S10, the method for producing the support structure 10 can start with providing the liquid medium 40 for shaping the support structure 10 during the production of the support structure 10 and/or in a production state of the support structure 10 in a defined amount. As already described above, the provided liquid medium 40 is received in the rotatably drivable receiving device 53 and acts as a shaping structure for the production of the support structure 10 by means of an adjusting curved surface 40.1 of the liquid medium 40. Preferably, there is a defined amount of liquid medium 40 provided in the receiving device 53, so that the surface 40.1 of the liquid medium 40 is substantially flush with a circumferential edge 53.2 of the receiving device 53, preferably during the operating state of the apparatus 1, in which the liquid medium 40 is moved through the receiving device 53 (see FIG. 1).

In step S10, a negative pressure and preferably a vacuum can be generated or run in the reaction chamber 30 by means of the pumping device 80 parallel in time or upstream in time with the provision of the liquid medium 40. In this way, for example, the formation of turbulent flows of the reaction material W in the reaction chamber 30 can be avoided or at least substantially reduced.

Preferably, outgassing of the liquid medium 40 can be provided in the course of or during the provision of the liquid medium 40 and when a corresponding pressure is generated under vacuum. This prevents, for example, the subsequent formation of bubbles in the liquid medium 40 and/or the occurrence of splashes in the liquid medium 40. As already described, the liquid medium 40 is preferably characterized by a comparatively high viscosity and/or by a comparatively high density and/or by a comparatively low vapor pressure.

In step S20, the liquid medium 40 is moved and thus set in motion by moving the receiving device 53. In other words, the liquid medium 40 and, in particular, the shaping surface 40.1 of the liquid medium 40 is set in a rotary or rotational motion via the receiving device 53. Preferably, a defined rotational speed n53 is set at the receiving device 53 and the receiving device 53 is operated at least over a period of time until a substantially identical resulting and/or idealized rotational speed n40 is set for the liquid medium 40 as the rotational speed n53 of the receiving device 53. The liquid medium 40 is preferably in a quasi-stationary (rotational motion) state in which, for example, no acceleration of particles (molecules) of the liquid medium 40 to a certain speed takes place.

In a further alternative embodiment of the apparatus 1 according to the invention and the method according to the invention, it is possible that in step S20, instead of the receiving device 53, the reaction container 50 of the apparatus 1 is set into a rotational movement as a whole in order to achieve a corresponding movement of the liquid medium 40 and in particular of the shaping surface 40.1.

In step S30, the reaction material W is provided for forming the support structure 10. The provision of the reaction material W in the reaction chamber 30 is realized in the apparatus 1 via the at least one inlet device 51 and/or preferably the distribution device 100. Before the provision in the reaction chamber 30, the reaction material W can be brought into a reactive monomeric state by evaporation via heating in the evaporation device 60 and/or by pyrolysis in the pyrolysis device 70 and thus by cracking, and is preferably present in a reactive gaseous aggregate state at the latest when it enters the reaction chamber 30.

The reactive aggregate state of the reaction material W preferably characterizes an operating condition, i.e. a state in which it is possible to construct the support structure 10 on the moving, shaping surface 40.1 of the liquid medium 40. As already described, the reaction material W is preferably a separable reaction material W from the group of poly-p-xylylenes and/or their derivatives (also referred to as “parylenes”). The reaction material W is distributed accordingly in the reaction chamber 30.

In step S40, the reaction material W is applied to the shaping surface 40.1 of the moving liquid medium 40. Here, the first particles of the reaction material W initially adhere to the surface 40.1 of the liquid medium 40 after the transition from the gaseous aggregate state to the solid aggregate state. As already described, the surface 40.1 of the liquid medium 40 serves as a shaping surface 40.1 for the support structure 10 to be produced as a result of the rotational movement of the liquid medium 40. The liquid medium 40 is preferably characterized by a resulting substantially constant velocity n40 with respect to its movement.

In step S50, a construction and thus a growth, preferably a continuous and/or steady construction, of the support structure 10 by particles of the reaction material W on already existing particles of the reaction material W on the surface 40.1 takes place. The construction of the support structure 10 can preferably comprise accumulating, preferably adsorbing, of the reaction material W on the shaping surface 40.1 and/or on the reaction material W already present on the shaping surface 40.1 in a solid aggregate state, and generating of chemical bonds in the reaction material W, that is, chemical bonds between particles (molecules) of the reaction material W. In other words, a construction and solidification of the support structure 10, that is, of the enriched reaction material W in the form of at least one layer and/or at least one membrane of the reaction material W, takes place.

Preferably, the enrichment and/or adsorption of the reaction material W at least partially concerns or comprises a chemical vapor deposition of the reaction material W for producing the support structure 10. The produced support structure 10 is sufficiently dimensionally stable to support a functional unit 20. The support structure 10 is preferably dimensionally stable in the production state, at least in sections, and/or reversibly foldable and/or reversibly rollable. Thus, the support structure 10 is capable of assuming or forming its original state, preferably production state, after folding and/or after rolling up. This is ensured in particular by sufficient dimensional stability of the support structure 10.

It is understood that in step S50 a more or less continuous detecting of the thickness 10.2 of the support structure 10 construction to a respective point in time by the measuring device 90 takes place parallel in time with the construction of the support structure 10. Detecting geometric dimensions of the support structure 10 can be realized, for example, using a spectral reflection method.

In order to construct, preferably deposit, the reaction material W on the surface 40.1 at different points or regions in a targeted manner, i.e. in a defined manner, the distributing device 100 can be coupled to at least one actuatable actuator device inside the reaction chamber 30 in a position-adjustable manner in order to change the position and/or the orientation of the distributing device 100 relative to the surface 40.1 and/or the receiving device 53.

In step S60, after the support structure 10 is produced, coating of the support structure 10, that is, the surface 10.1 of the support structure 10, with a coating material B can take place. The coating material B can preferably take place via the coating device 120 by evaporation and/or atomization in the reaction chamber 30 and further onto the support structure 10, that is, onto the surface 10.1 of the support structure 10 under corresponding operating conditions. Preferably, a sufficient vacuum prevails in the reaction chamber 30 at least during the coating of the support structure 10 with the coating material B, which allows the formation of the coating and thus of the functional unit 20 on the support structure 10. Furthermore, appropriate regulation and/or control of a valve device between the evaporation device 60 and the pyrolysis device 70 can also contribute to the formation of a defined thickness 10.2 of the support structure 10.

It is possible or it is understood that certain process steps can, for example, run in parallel in terms of time, for example generation of a negative pressure and/or a vacuum and vaporization and/or pyrolysis of the reaction material W. Furthermore, it is possible that in a first embodiment of the method a first method step takes place before a second method step and in a further, alternative embodiment of the method the first method step takes place after the second method step. It is understood that respective or certain method steps can be combined with each other as desired, provided that this contributes to the formation of the support structure 10. For example, in one embodiment, the generation of a vacuum can begin before a movement of the liquid medium, while in a further alternative embodiment of the method according to the invention, a movement of the liquid medium can take place before the generation of a vacuum.

Thus, the method according to the invention and/or the apparatus 1 according to the invention can provide a support structure 10 which is configured to support a functional unit 20, wherein the support structure 10 is preferably characterized by a substantially constant thickness 10.2 and/or homogeneous distribution of the reaction material W, as well as by sufficient dimensional stability.

The support structure 10 together with the functional unit 20 as disclosed herein can be configured for use in and/or with an optical device. The present invention further relates to an optical device with at least one support structure as disclosed herein. The optical device can be configured as an optical telescope or an optical membrane mirror, or can comprise an optical telescope or an optical membrane mirror.

The present invention is not limited to the embodiments described above. Rather, a large number of variants and modifications are possible which also make use of the inventive concept and therefore fall within the scope of protection. Preferably, the present invention also claims protection for the subject matter and features of the subclaims independently of the claims referred to.

### LIST OF REFERENCE SYMBOLS

1 apparatus
10 support structure
10.1 surface of the support structure
10.2 thickness of the support structure
20 functional unit
20.2 thickness of the functional unit
30 reaction chamber
40 liquid medium
40.1 surface of the liquid medium
50 reaction container
50.1 container housing part
50.2 container housing part
51 inlet device
52 outlet device
53 receiving device
53.1 surface of the receiving device
53.2 edge of the receiving device
54 drive unit
55 bearing device
56 barrier device
57 damping device
60 evaporation device
70 pyrolysis device
80 pumping device
90 measuring device
100 distribution device
110 control device
120 coating device
130 cooling device
B coating material
n40 speed
n53 speed (rotation/rotational/angular speed)
S signal
W reactive material

1. A method for producing a support structure for supporting at least one functional unit in a reaction chamber, comprising:
providing a liquid medium for shaping the support structure during production or in a production state;
moving the liquid medium and generating a shaping surface of the liquid medium;
providing a reaction material for forming the support structure;
depositing the reaction material onto the shaping surface;
constructing the support structure using the deposited reaction material.

2. The method according to claim 1,
wherein the reaction material is configured as a gaseous or separable reaction material at least before the constructing of the support structure, or wherein the reaction material is configured as a solid reaction material at least after the constructing of the support structure.

3. The method according to claim 1, comprising:
evaporating the reaction material or transforming the reaction material from a solid aggregate state into a gaseous aggregate state; or
pyrolizing the reaction material.

4. The method according to claim 1,
wherein constructing the support structure comprises:
accumulating the reaction material on the shaping surface,
generating chemical bonds in the reaction material, or
constructing the support structure in the form of at least one layer or at least one membrane.

5. The method according to claim 1,
wherein moving the liquid medium comprises:
rotating the liquid medium at an adjustable speed; or
forming the shaping surface, which is configured to be curved or arched, at least in sections.

6. The method according to claim 1, comprising:
generating a negative pressure or a vacuum in the reaction chamber at least before the providing of the reaction material.

7. The method according to claim 1, comprising:
Directed distributing of the reaction material at at least one defined point in the reaction chamber.

8. The method according to claim 1, comprising:
Detecting a geometric variable of the support structure during the depositing of the reaction material or constructing of the support structure.

9. The method according to claim 1, comprising:
setting at least one operating condition of the method, wherein the at least one operating condition comprises at least one of the following: a temperature in the reaction chamber, a temperature of the reaction material before being provided in the reaction chamber, a pressure in the reaction chamber, a temperature of the liquid medium; a time period of the providing of the reaction material, a volume flow of the reaction material.

10. A support structure for supporting at least one functional unit, wherein the support structure is produced according to the method according to claim 1,
wherein the support structure is dimensionally stable at least in sections at least in the production state, or wherein the support structure (is reversibly foldable or reversibly rollable.

11. The support structure according to claim 10,
wherein the support structure is configured to be curved at least in sections, or
wherein the support structure is configured from a reaction material which comprises a material selected from the group consisting of poly-p-xylylenes and derivatives thereof.

12. The support structure according to claim 10,
wherein the support structure supports at least one functional unit, wherein the at least one functional unit comprises at least one coating or at least one layer, which is formed from a metallic material or from a light-reflecting material.

13. An optical device, comprising at least one support structure for supporting at least one functional unit according to claim 10.

14. An apparatus for producing a support structure for supporting at least one functional unit,
wherein the apparatus is configured to carry out the method according to claim 1,
comprising:
a reaction chamber, which is formed by a reaction container and in which the support structure is producible;
a receiving device for receiving a liquid medium for shaping the support structure during the production or in a production state, wherein the receiving device is arranged in the reaction chamber or is configured to be semi-open at least in sections;
at least one inlet device for providing a reaction material into the reaction chamber and forming the support structure;
wherein the receiving device comprises a drive device or is coupled to a drive device in order to move a received liquid medium and to generate a shaping surface of the liquid medium,
wherein the reaction chamber or at least the at least one inlet device is configured for applying the reaction material onto the shaping surface in order to construct the support structure through it.

15. The apparatus according to claim 14,
wherein the drive device is configured to rotationally drive the receiving device at an adjustable speed.

16. The apparatus according to claim 14,
wherein the apparatus comprises at least one bearing device for bearing the receiving device, wherein the at least one bearing device is configured for vibration-free bearing of the receiving device.

17. The apparatus according to claim 16,
wherein the apparatus comprises at least one barrier device for protecting the at least one bearing device in order to prevent the reaction material from entering the at least one bearing device,
wherein the at least one barrier device encloses the at least one bearing device or comprises at least one labyrinth seal and/or at least one liquid seal.

18. The apparatus according to claim 14,
wherein the apparatus comprises a coating device for coating the support structure with a coatable material in order to form the at least one functional unit on the support structure.

19. A method for producing a mirror comprising a support structure for supporting at least one functional unit, comprising:
producing the support structure according to claim 1, and
applying or coating of at least one functional unit on a concave side of a curved or arched surface of the support structure, wherein the at least one functional unit comprises at least one coating or at least one layer, which is formed from a metallic material or from a light-reflecting material.

20. A mirror, comprising:
a support structure, wherein the support structure is configured according to claim 10, and
at least one functional unit being formed on a concave side of a curved or arched surface of the support structure.
